(19) United States
(12) Patent Application Publication
(10) Pub. No.: US 2026/0266877 A1
(43) Pub. Date: Sep. 10, 2026

(54) MOTOR AND BEARING CURRENT MEASUREMENT SYSTEM INCLUDING THE SAME

(71) Applicants: HYUNDAI MOTOR COMPANY, SEOUL (KR); KIA CORPORATION, SEOUL (KR)

(72) Inventors: Sang In Lee, Hwaseong-si (KR); Sung Sik Kong, Hwaseong-si (KR); Seung Ho Ahn, Hwaseong-si (KR); Chan Song Lee, Hwaseong-si (KR); Seok Bae Moon, Hwaseong-si (KR); Byung Su Kim, Hwaseong-si (KR); Dong Gon Kang, Hwaseong-si (KR)

(73) Assignees: HYUNDAI MOTOR COMPANY, SEOUL (KR); KIA CORPORATION, SEOUL (KR)

(21) Appl. No.: 19/557,669

(22) Filed: Mar. 5, 2026

(30) Foreign Application Priority Data
Mar. 5, 2025 (KR) 10-2025-0028468

(51) Int. Cl. G01R 19/00; G01M 13/04

(52) U.S. Cl. CPC G01R 19/0046; G01M 13/04

(57) ABSTRACT

A motor is provided. The motor includes a housing, a shaft passing through at least a portion of the housing, and a bearing portion coupled to the housing and supporting the shaft. The bearing portion includes a bearing, a bearing cover surrounding the bearing, and a conductive ring coupled to the bearing cover and in contact with the bearing.

### CROSS-REFERENCE TO RELATED APPLICATIONS

This application claims benefit of priority to Korean Patent Application No. 10-2025-0028468 filed on Mar. 5, 2025 in the Korean Intellectual Property Office, the disclosure of which is incorporated herein by reference in its entirety.

### TECHNICAL FIELD

The present disclosure relates to a motor and a bearing current measurement system.

### BACKGROUND

A driving motor may be used as a device in various industrial fields such as manufacturing, energy, and transportation. A bearing may support a rotating component of the motor to minimize friction and maintain the performance and reliability of the motor. However, in an inverter-based motor control system, an electrochemical current may occur in a bearing portion of the motor, which may cause bearing damage. As a result, abnormal noise, degradation of motor performance, malfunctioning, or the like may occur.

In one approach, a bearing state may be indirectly monitored by measuring a common mode voltage (CMV). However, the CMV is not entirely converted into the electrochemical current of the bearing portion, which may result in a limitation in accurately measuring the electrochemical current. In addition, direct measurement of the electrochemical current may incur high installation costs and technical complexity, which may make practical use in industrial sites challenging.

### SUMMARY

An example embodiment of the present disclosure is to provide a motor for (e.g., directly) measuring an electrochemical current flowing through a bearing, and a bearing current measurement system including the same.

Another example embodiment of the present disclosure is to provide a motor for facilitating measurement of the electrochemical current flowing through a bearing by reducing a physical distance between the motor and the bearing, and a bearing current measurement system including the same.

According to an example embodiment of the present disclosure, a motor is provided. The motor includes a housing, a shaft passing through at least a portion of the housing, and a bearing portion coupled to the housing and supporting the shaft. The bearing portion includes a bearing, a bearing cover surrounding the bearing, and a conductive ring coupled to the bearing cover and in contact with the bearing.

A diameter of the bearing cover may be greater than a diameter of the bearing.

The bearing cover may include a bearing space in which the bearing is disposed, and a ring space which is connected to the bearing space. The conductive ring may be disposed in the ring space.

A width of the bearing space may be greater than a width of the ring space.

The bearing cover may include an insulating material.

A width of the bearing cover may be greater than a width of the bearing.

According to another example embodiment of the present disclosure, a bearing current measurement system is provided. The bearing current measurement system includes a motor, and a data collection system electrically connected to the motor. The motor includes a housing, a shaft passing through at least a portion of the housing, and a bearing portion coupled to the housing and supporting the shaft. The bearing portion includes a bearing, a bearing cover disposed between the bearing and the housing, and a conductive ring coupled to the bearing cover and in contact with the bearing.

The conductive ring may be electrically connected to the data collection system.

The data collection system may be electrically connected to the housing.

The motor may further include a rotor coupled to the shaft and rotating together with the shaft, and a stator surrounding the rotor and supported by the housing.

### BRIEF DESCRIPTION OF DRAWINGS

The above and other example embodiments, features, and advantages of the present disclosure will be more clearly understood from the following detailed description, taken in conjunction with the accompanying drawings.

FIG. 1 is a perspective view illustrating a bearing current measurement system according to an example embodiment of the present disclosure.

FIG. 2 is a cross-sectional view illustrating a motor according to an example embodiment of the present disclosure.

FIG. 3 is an exploded perspective view illustrating a bearing portion according to an example embodiment of the present disclosure.

### DETAILED DESCRIPTION

The present disclosure may have various modifications and various example embodiments, and specific example embodiments will be illustrated in the drawings and described in detail. However, the scope of the present disclosure is not limited to specific example embodiments, and includes (e.g., all) modifications, equivalents, or substitutes included within the spirit and scope of the present disclosure.

Terms such as “first” or “second” may be used to describe various components, and the components are not to be construed as being limited by these terms. The terms are used (e.g., only) to distinguish one component and another component from each other. For example, a “first” component may be referred to as a “second” component and the “second” component may also be referred to as the “first” component, without departing from the scope of the present disclosure. A term “and/or” includes a combination of a plurality of related described items or any one of the plurality of related described items.

Terms such as “unit,” “part,” or “portion,” “units,” “parts,” or “portions,” may be used to describe various components, and the components should not be limited by these terms. The terms may refer to physically and/or visibly distinguishable components, and also may refer to components in which functions or configurations of the corresponding portions are described although separation or partition thereof is not (e.g., clearly) provided (e.g., defined).

Terms used in the present disclosure are used (e.g., only) to describe specific example embodiments and are not intended to limit the present disclosure. A term of a singular number may include its plural number unless the context (e.g., clearly) indicates otherwise. In the present disclosure, terms such as “include” or “have” are intended to designate that features, numbers, steps, operations, components, parts, or combinations thereof described in the specification are present, and do not preclude the presence or addition of one or more other features, numbers, steps, operations, components, parts, or combinations thereof.

Unless otherwise provided (e.g., defined), (e.g., all) terms used herein, including technical or scientific terms, have the same meaning as those generally understood by those skilled in the art to which the present disclosure pertains. Terms generally used and defined in dictionaries should be interpreted as having meanings consistent with those in the context of the related art, and should not be interpreted as having idealized or overly formal meanings unless explicitly defined in the present disclosure.

In the following description, terms related to directions, such as “front,” “rear,” “side,” “forward,” “backward,” “upper,” “lower,” “upward,” “downward,” “left,” and “right” are provided (e.g., defined) based on a motor MT. In addition, terms such as “first” and “second” may be used to describe various components; however, the components are not limited in order, size, position, or importance by such terms, and each term may be assigned (e.g., solely) for a purpose of distinguishing one component from another component.

Hereinafter, example embodiments of the present disclosure will be described in detail with reference to the accompanying drawings.

In the drawings, a direction D1 may be referred to as a first direction D1, a direction D2 (e.g., intersecting the first direction D1) may be referred to as a second direction D2, and a direction D3 (e.g., intersecting both the first direction D1 and the second direction D2) may be referred to as a third direction D3. The third direction D3 may be referred to as an upward direction, and a direction opposite to the third direction D3 may be referred to as a downward direction. Each of the first direction D1 and the second direction D2 may be referred to as a horizontal direction.

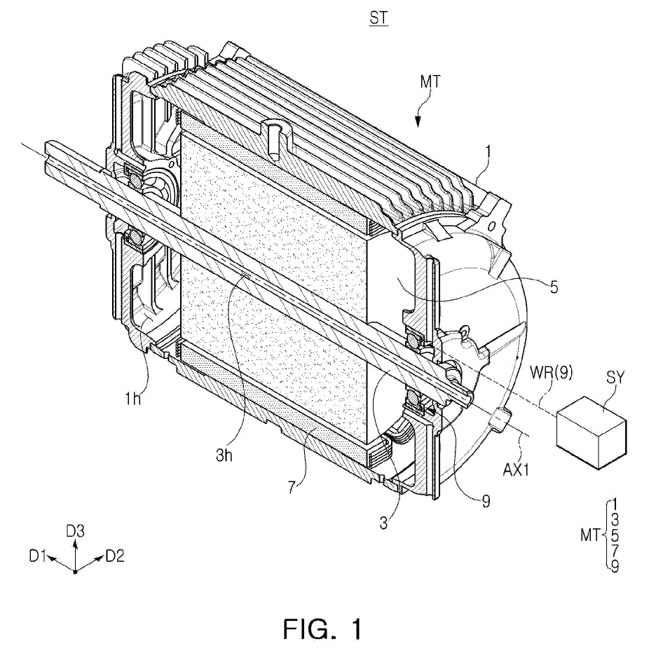

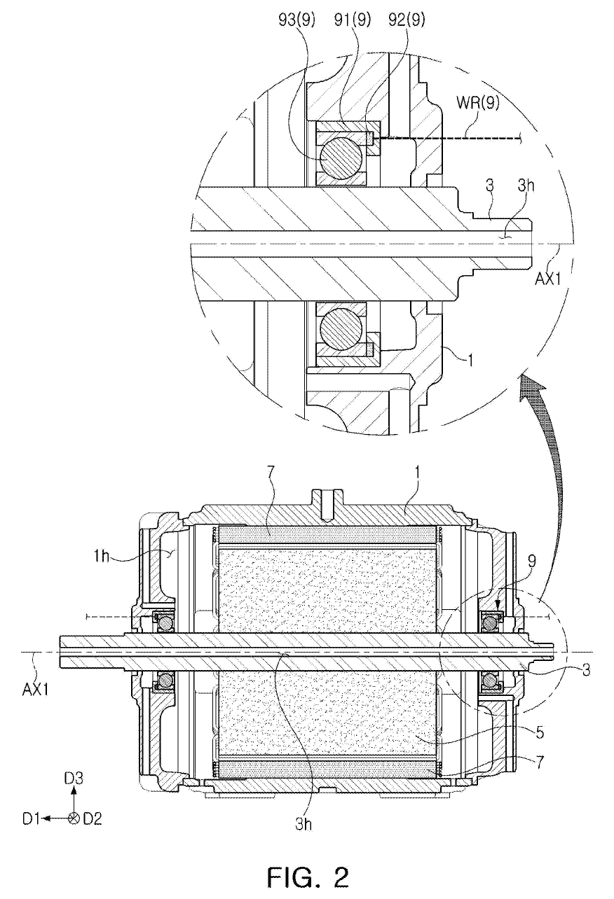

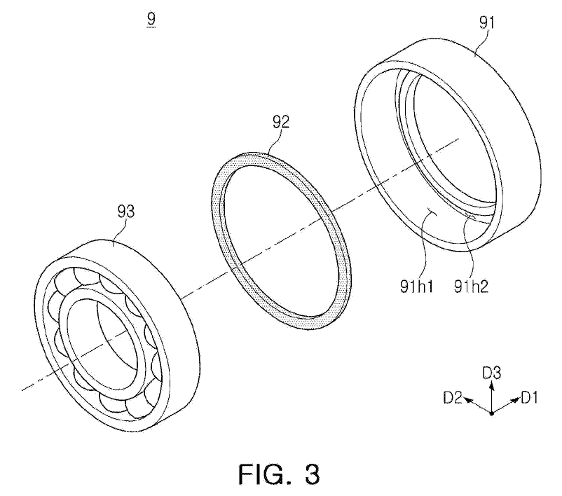

FIG. 1 is a perspective view illustrating a bearing current measurement system ST according to an example embodiment of the present disclosure, FIG. 2 is a cross-sectional view illustrating the motor MT according to an example embodiment of the present disclosure, and FIG. 3 is an exploded perspective view illustrating a bearing portion 9 according to an example embodiment of the present disclosure.

Referring to FIGS. 1 and 2, the bearing current measurement system ST according to an example embodiment may include the motor MT and a data collection system SY. The motor MT according to an example embodiment may include a housing 1, a shaft 3, and a bearing portion 9 The motor MT may optionally include a rotor 5 and a stator 7.

The bearing current measurement system ST may measure a current flowing through a bearing 93. By measuring the current flowing through the bearing 93, the bearing current measurement system ST may predict (e.g., or determine) a degree of wear (e.g., progression) of the bearing 93. The bearing current measurement system ST may measure a bearing current that is a (e.g., direct) cause of damage to the bearing 93, thereby preventing or managing wear of the bearing 93.

The housing 1 may include an internal space 1h. The housing 1 may support the shaft 3, the stator 7, the rotor 5, and the bearing portion 9. However, a structure of the motor MT supported by the housing 1 is not limited thereto. The housing 1 may have a cylindrical shape, and the shape of the housing 1 is not limited thereto. The housing 1 may have a first axis AX1 extending in the first direction D1 as a central axis.

The shaft 3 may pass through at least a portion of the housing 1. The shaft 3 may extend toward the internal space 1h. The shaft 3 may have the first axis AX1 as a central axis. The shaft 3 may extend toward the internal space 1h while having the first axis AX1 as the central axis. The shaft 3 may rotate while having the first axis AX1 as the central axis. The shaft 3 may include a through space. The shaft 3 may include a through portion 3h. The through portion 3h may extend in the first direction D1 while having the first axis AX1 as a central axis. However, the shape of the shaft 3 is not limited thereto, and the shaft 3 may not include the through portion 3h.

The stator 7 may be coupled to the housing 1. The stator 7 may be supported by the housing 1. The stator 7 may surround the rotor 5. The stator 7 may surround at least a portion of the shaft 3.

The stator 7 may include a core structure wound with coils. The core may be formed of a highly conductive magnetic material to minimize magnetic loss and may provide an (e.g., efficient) magnetic flux path. The core may have a slot structure for (e.g., substantially uniformly) distributing magnetic flux density.

The coils may include copper or aluminum wires. The coils may be (e.g., substantially uniformly) wound in each slot of the stator 7 to form a rotating magnetic field for driving the rotor through a three-phase alternating current. The coils may be covered with an insulating coating or insulating film to prevent or minimize short circuits.

However, the structure of the stator 7 is not limited thereto. The stator 7 may have a slotless structure (e.g., without slots) and may have various shapes. For example, the stator 7 may include permanent magnets.

The rotor 5 may rotate together with the shaft 3. The rotor 5 may rotate while being coupled to the shaft 3. The rotor 5 may surround at least a portion of the shaft 3. However, the coupling between the rotor 5 and the shaft 3 is not limited thereto.

The rotor 5, according to an example embodiment, may include a core. The rotor 5, according to an example embodiment, may optionally include permanent magnets or coils. The permanent magnets may be attached to or embedded in the core of the rotor. A magnetic force may be generated between the permanent magnets of the rotor 5 and the permanent magnets of the stator 7 by an alternating magnetic field generated by the stator 7, thereby providing (e.g., enabling) rotational motion of the rotor 5. The permanent magnets may include at least one of neodymium (Nd), iron (Fe), boron (B), samarium, cobalt, alnico, or ferrite, and the material of the permanent magnets is not limited thereto.

The coil may be wound around the core of the rotor 5. The coil may generate an induced current inside the rotor and may interact with the magnetic field generated by the stator 7. The coil may include copper (Cu); however, the type of conductive coil is not limited thereto.

The rotor 5 may rotate by interacting with the stator 7. For example, when an alternating current is supplied to the stator 7, a change in the magnetic field may be generated due to a change in a current flowing through the stator 7. Due to the change in the magnetic field generated by the stator 7, an induced current may be generated in the rotor 5. An electromagnetic force may be generated in the rotor 5, and thus, the rotor 5 may rotate. In addition, when a direct current is supplied to the rotor 5, the rotor 5 may receive an electromagnetic force in the magnetic field formed by the stator 7 and rotate. For example, the rotor 5 may (e.g., optionally) include a commutator to change a direction of a current flowing in the same direction.

The bearing portion 9 may support the shaft 3. The bearing portion 9 may be coupled to the housing 1. The bearing portion 9 may be disposed between the shaft 3 and the housing 1. The shaft 3 may rotate relative to the housing 1 by the bearing portion 9. According to an example embodiment, the bearing portion 9 may include the bearing 93, a bearing cover 91, and a conductive ring 92. The bearing portion 9 may (e.g., optionally) include a wire WR.

The bearing 93 may support the shaft 3. The bearing 93 may be disposed between the shaft 3 and the housing 1. The bearing 93 may allow the shaft 3 to rotate relative to the housing 1. The bearings 93 may be disposed on both sides of the shaft 3. A plurality of bearings 93 may be provided. However, herein, the plurality of bearings 93 may be described as a single bearing. The bearing 93 may surround at least a portion of the shaft 3.

The bearing cover 91 may (e.g., substantially) surround the bearing 93. The bearing cover 91 may be disposed between the bearing 93 and the housing 1. The bearing cover 91 may include an insulating material. For example, the bearing cover 91 may include or be provided in the form of at least one of rubber, ceramic, plastic, silicone, synthetic resin, and/or polytetrafluoroethylene (PTFE). However, the type of the bearing cover 91 and/or the material of the bearing cover 91 is not limited thereto, and the bearing cover 91 may include various materials capable of electrically insulating the bearing 93 from the housing 1.

Referring to FIGS. 2 and 3, a diameter of the bearing cover 91 may be greater than a diameter of the bearing 93. A width of the bearing cover 91 may be greater than a width of the bearing 93. A width of the bearing cover 61 or the bearing 93 is a length in a direction D1 in FIG. 3. The bearing cover 91 may include a bearing space 91h1 in which the bearing 93 may be disposed. The bearing space 91h1 is an inner space of the bearing cover 91 having ring shape for accommodating the bearing 93.

The conductive ring 92 may be coupled to the bearing cover 91. The bearing cover 91 may include a ring space 91h2 in which the conductive ring 92 may be disposed. The conductive ring 92 may be in contact with the bearing 93. For example, the conductive ring 92 may be in contact with an outer ring of the bearing 93. The conductive ring 92 may be electrically connected to the bearing 93. The ring space 91h2 may be connected to (e.g., and/or adjacent) the bearing space 91h1 to allow the conductive ring 92 to be in contact with the bearing 93.

The conductive ring 92 may include and/or be provided in the form of at least one of copper (Cu), aluminum (Al), iron (Fe), and/or nickel (Ni). The material of the conductive ring 92 is not limited thereto.

The bearing 93 may overlap (e.g., at least) one side of the conductive ring 92. A width of the conductive ring 92 may be smaller than a width of the bearing 93. A width of the bearing space 91h1 may be greater than a width of the ring space 91h2. A Width of the conductive ring 92 or the bearing 93 is a length in a direction D1 in FIG. 3.

When the rotor 5 rotates, an electromagnetic field may be generated, and a voltage may thus be induced between the shaft 3 and structures surrounding the shaft 3. Due to the induced voltage, a current may flow along a discharge path. When the current generated by the induced voltage flows through the bearing 93, the bearing current may flow.

When the bearing current flows through the bearing 93, discharge may occur, and minute pits may be formed on a metal surface of the bearing 93. In addition, a (e.g., high-temperature) environment may be generated due to (electrical) discharge on the surface of the bearing 93, and lubricant may be impacted (e.g., damaged), thereby increasing friction between the bearing 93 and the shaft 3 and friction inside the bearing 93. As the surface of the bearing 93 is impacted (e.g., damaged), vibration may be induced, and performance of the bearing 93 may be impacted (e.g., degraded). Accordingly, when the bearing current flows through the bearing 93, the performance of the bearing 93 may be degraded, and/or a lifespan of the bearing 93 may be reduced, which may lead (e.g., expand) to a defect in the (e.g., entire) motor MT.

The wire WR may be electrically connected to the conductive ring 92. The wire WR may be exposed outside (e.g., outward) of the housing 1. The wire WR may be electrically connected to the data collection system SY. When the bearing current flows through the bearing 93, the bearing current may move to the conductive ring 92 and then be discharged outward through the wire WR. The data collection system SY may receive the bearing current transmitted from the conductive ring 92 and then collect and analyze the bearing current discharged when the rotor 5 is rotating. The data is collected for checking and determining whether the discharge is over the limit or not.

The data collection system SY may be electrically connected to the conductive ring 92 and also to the housing 1. The data collection system SY may be connected to the conductive ring 92 and the housing 1 to (e.g., directly) measure the bearing current. According to an example embodiment, the data collection system SY may include a data acquisition (DAQ) device and a computer, such that, for example, the system may collect and/or evaluate an electrical discharge to determine if the discharge is greater than or less than a (e.g., predetermined) limit and then a decision can be made on the performance and/or reliability of the bearing and/or the motor. The DAQ device may convert a physical signal into a digital data to allow the computer to process or store the digital data. According to an example embodiment, the DAQ device may (e.g., optionally) include a signal conditioning device, a converter, a digital input/output device, or a communication interface. The signal conditioning device may convert a signal detected from the conductive ring 92 into a form processable by the DAQ device. The signal conditioning device may amplify, filter, and/or convert the signal detected from the conductive ring 92, or the like. The converter may convert an analog signal into a digital signal. The digital input/output device may collect digital data or transmit command signals. The communication interface may transmit and receive data to and/or from the DAQ device and the computer. The computer may receive data from the DAQ device and then process and visualize the data, such as plotting a discharge and a time, for example, on a graph. The data collection system SY may be disposed outside the housing 1.

The motor MT and the bearing current measurement system ST including the same, according to the example embodiments of the present disclosure, may facilitate management of the bearing 93 by (e.g., directly) measuring the bearing current. Electrochemical corrosion occurring in the bearing 93 may be related to a lifespan of the bearing 93, to a degree of wear of the bearing 93, and/or to a lifespan of the entire motor MT. Accordingly, the bearing current may (e.g., need to) be (e.g., continuously) managed. The bearing current measurement system ST may (e.g., continuously) observe, record, and analyze the bearing current to determine the wear and corrosion occurring in the bearing 93. Accordingly, the bearing current measurement system ST may facilitate the management of the bearing 93 and improve (e.g., enhance) safety of the motor.

As set forth above, according to an example embodiment of the present disclosure, the motor and the bearing current measurement system including the same may (e.g., directly) measure an electrochemical current flowing through the bearing.

According to an example embodiment of the present disclosure, the motor and the bearing current measurement system including the same may facilitate measurement of an electrochemical current flowing through the bearing by reducing the physical distance between the motor and the bearing.

While the example embodiments have been shown and described above, it will be apparent to those skilled in the art that modifications and variations could be made without departing from the scope of the present disclosure as provided (e.g., defined) by the appended claims.

What is claimed is:

1. A motor comprising:
a housing;
a shaft passing through at least a portion of the housing; and
a bearing portion coupled to the housing and supporting the shaft,
wherein the bearing portion includes:
a bearing;
a bearing cover surrounding the bearing; and
a conductive ring coupled to the bearing cover and in contact with the bearing.

2. The motor according to claim 1, wherein a diameter of the bearing cover is greater than a diameter of the bearing.

3. The motor according to claim 1, wherein the bearing cover includes:
a bearing space in which the bearing is disposed.

4. The motor according to claim 3, wherein the bearing cover further includes a ring space connected to the bearing space.

5. The motor according to claim 4, wherein the conductive ring is disposed in the ring space.

6. The motor according to claim 5, wherein a width of the bearing space is greater than a width of the ring space.

7. The motor according to claim 1, wherein the bearing cover includes an insulating material.

8. The motor according to claim 1, wherein a width of the bearing cover is greater than a width of the bearing.

9. A bearing current measurement system comprising:
a motor; and
a data collection system electrically connected to the motor,
wherein the motor includes:
a housing;
a shaft passing through at least a portion of the housing; and
a bearing portion coupled to the housing and supporting the shaft, and
the bearing portion includes:
a bearing;
a bearing cover disposed between the bearing and the housing; and
a conductive ring coupled to the bearing cover and in contact with the bearing.

10. The system according to claim 9, wherein the conductive ring is electrically connected to the data collection system.

11. The system according to claim 10, wherein the data collection system is electrically connected to the housing.

12. The system according to claim 9, wherein the motor further includes
a rotor coupled to the shaft.

13. The system according to claim 12, wherein the rotor is configured to rotate together with the shaft.

14. The system according to claim 13, wherein the motor further includes
a stator surrounding the rotor.

15. The system according to claim 14, wherein the stator is supported by the housing.

16. The system according to claim 9, wherein a diameter of the bearing cover is greater than a diameter of the bearing.

17. The system according to claim 9, wherein the bearing cover includes:
a bearing space in which the bearing is disposed; and
a ring space connected to the bearing space.

18. The system according to claim 17, wherein the conductive ring is disposed in the ring space.

19. The system according to claim 17, wherein a width of the bearing space is greater than a width of the ring space.

20. The system according to claim 9, wherein the bearing cover includes an insulating material, and a width of the bearing cover is greater than a width of the bearing.
